(19) United States
(12) Patent Application Publication
(10) Pub. No.: US 2002/0015906 A1
(43) Pub. Date: Feb. 7, 2002

(54) Polymer for photoresist, method of production thereof and photoresist composition containing polymer

(76) Inventors: Sang Kyun Lee, Deajun-Shi (KR); Bong Seok Moon, Daejun-Shi (KR); Chang Ho Noh, Daejun-Shi (KR)

Correspondence Address: The Law Offices of Eugene M Lee, PLLC, 2111 Wilson Boulevard, Suite 1200, Arlington, VA, 22201, US

(21) Appl. No.: 09/810,416

(22) Filed: Mar. 19, 2001

(30) Foreign Application Priority Data
Jul. 29, 2000 (KR) 2000-44028

(51) Int. Cl. C08F 12/24; G03F 7/004

(52) U.S. Cl. 430/170; 430/905; 430/270.1; 522/31; 526/313

(57) ABSTRACT

A polymer for a photoresist composition is given by the formula (I):

[chemical structure]

wherein R¹ is a hydrogen atom or a methyl group, R² is a C₁₋₁₂ linear or branched alkyl, haloalkyl or alkoxycarbonyl group, a C₅₋₁₂ cyclic alkyl, cyclic haloalkyl or cyclic alkoxycarbonyl group, a phenyl group or a naphthyl group, R³ is a C₁₋₁₂ linear or branched alkyl or haloalkyl group, a C₅₋₁₂ cyclic alkyl or cyclic haloalkyl group, a phenyl group, or a naphthyl group, R⁴ and R⁵ are independently a hydrogen atom, a C₁₋₆ linear or branched alkyl, or a C₅₋₆ cyclic alkyl group, R′ and R″ are independently a hydrogen atom, a halogen atom, a C₁₋₈ alkyl or alkoxy group, a hydroxy group, a carbonate group or a phenyl group, and m, n, p and q are independently an integer provided that m and q are not zero, at least one of n and p are not zero, 0.4≦m/(m+n+p+q)≦0.9, 0≦n/(m+n+p+q)≦0.5, 0≦p/(m+n+p+q)≦0.5, and 0.01≦q/(m+n+p+q)≦0.3.

### BACKGROUND OF THE INVENTION

1. Field of the Invention

The present invention relates to a polymer for a photoresist composition, a method of the polymer, and a photoresist composition containing the polymer. The polymer is used for forming micropatterns on the surface of a semiconductor device using UV (ultraviolet light) or deep UV.

2. Description of Background Art

Presently, the bit number of a memory element, which is integrated into an IC chip, has reached the megabite level in accordance with the technological development of LSI (Large Scale Integration). As a result, a submicron rule is required because the interval between lines and spaces has become minute. Therefore, the wavelengths of light sources used for lithography have been shortened. In addition, etching processes used in LSI typically are dry etching processes using a PF plasma. Resist materials used in this process technology must have good sensitivity to light, transparency, etch resistance, etc. Under these conditions, novolak type aromatic resins, which have good light transmittance and plasma etch resistance, have been used as a photoresist, especially for lithography technology using g-line and i-line. However, when a light source such as mercury, etc. is used, an ArF or KrF beam is much weaker than g-line or i-line, so that traditional resist materials for g-line or i-line cannot bring the required sensitivity to exposure to light if deep UV is applied. Furthermore, the transmittance for deep UV is lowered. For that reason, resist materials of new types have been developed.

To resolve these problems, resist materials of the chemical-amplification type have been developed to replace conventional resist materials. For example, Japanese Laid-Open Publication No. Sho 59-45439 provides a resist material which consists of p-tert-butoxycarbonyloxy-α-methylstyrene polymer having a functional group that is unstable to acid, repeatedly, and diallyliodonium which generates acid when exposed to light. When this resist material is exposed to light, diallyliodonium is decomposed to generate an acid, and the p-tert-butoxy group of p-tert-butoxy-carbonyloxy-α-methylstyrene is decomposed by the generated acid to produce a functional group having polarity. Accordingly, the field which is exposed to light or not, can be dissolved in basic or non-polar solvent to produce the required pattern. Furthermore, Japanese Laid-Open Publication No. Sho 62-115440 describes a method of dissolving poly-4-tert-butoxy-α-methylstyrene together with (tert-butylphenyl)iodonium trifluoromethanesulfonate, followed by exposure to deep UV. It is known that the method achieves good results when it is used together with the above resist material of Japanese Application Laid Open No. Sho 59-45439. These basic resins for resist materials employing chemical amplification have been developed centering on polyhydroxystyrene (PHST), which has already been widely used.

In the beginning of development, almost polymers were produced by changing the pendant group of homo substituted styrene-type polymers. But there were problems with sensitivity, contrast, etch resistance, etc., so various experiments were performed to remove these problems. Copolymers were proposed as possible solutions. Homopolymers were characterized by poor preservation, decrease of volume due to deprotection of the pendant groups, poor sensitivity, solubility to alkali developing solutions, etc. Thus, copolymers of styrene having hydroxystyrene and acetal groups are described in Japanese Laid-Open Publication Nos. Hei 2-291559, 4-26850 and 4-321949, and in German Patent No. 4,007,924. Polymers containing ester groups and silicone groups are also described in European Patent Nos. 424737, 476865 and 536997, and in Japanese Laid Open Publication No. Hei 5-19482. These inventions use acetal groups and the like to form micropatterns, but the amount of substitution is limited because these protection groups have poor dry-etch properties in etch processes.

Furthermore, to form micropatterns under 0.15 μm L/S, the film must be thin. Accordingly, materials having good etch resistance are needed.

### SUMMARY OF THE INVENTION

A feature of an embodiment of the present invention is to provide a novel polymer for a photoresist composition, which is prepared by using stilbene as a co-monomer in a copolymer for the photoresist composition.

Another feature an embodiment of the present invention is to provide a method for producing the novel polymer.

Still another feature of an embodiment of the present invention is to provide a photoresist composition of the chemical-amplification type having improved properties such as micropattern formation and etch resistance.

In accordance with one aspect of an embodiment of the present invention, there is provided a polymer for a photoresist composition which is represented by the following formula (I):

[chemical structure]

wherein R¹ is a hydrogen atom or a methyl group, R² is a C₁₋₁₂ linear or branched alkyl, haloalkyl or alkoxycarbonyl group, a C₅₋₁₂ cyclic alkyl, cyclic haloalkyl or cyclic alkoxycarbonyl group, a phenyl group or a naphthyl group, R³ is a C₁₋₁₂ linear or branched alkyl or haloalkyl group, a C₅₋₁₂ cyclic alkyl or cyclic haloalkyl group, a phenyl group, or a naphthyl group, R⁴ and R⁵ are independently a hydrogen atom, a C₁₋₆ linear or branched alkyl, or a C₅₋₆ cyclic alkyl group, R′ and R″ are independently a hydrogen atom, a halogen atom, a C₁₋₈ alkyl or alkoxy group, a hydroxy group, a carbonate group or a phenyl group, and m, n, p and q are independently an integer provided that m and q are not zero, at least one of n and p are not zero, 0.4≦m/(m+n+p+q)≦0.9, 0≦n/(m+n+p+q)≦0.5, 0≦p/(m+n+p+q)≦0.5, and 0.01≦q/(m+n+p+q)≦0.3.

In accordance with another aspect of an embodiment of the present invention, there is provided a photoresist composition comprising (a) a polymer as described above; (b) a photoacid generator; and (c) a solvent which dissolves the components (a) and (b).

In accordance with still another aspect of the present invention, there is provided a method of producing the above polymer which comprises the steps of

(i) anion-polymerizing at least one monomer of the following formula (II)

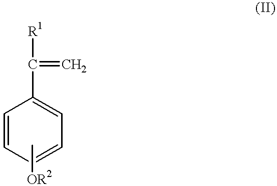

wherein R¹ is a hydrogen atom or a methyl group, and R² is a C₁₋₁₂ linear or branched alkyl, haloalkyl or alkoxycarbonyl group, a C₅₋₁₂ cyclic alkyl, cyclic haloalkyl or cyclic alkoxycarbonyl group, a phenyl group or a naphthyl group, with a stilbene monomer of the following formula (IV)

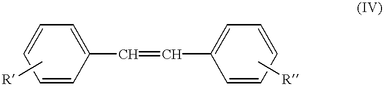

and

(ii) hydrolyzing or substituting with an acetal at least a part of the polymerized monomer of the formula (II).

Other features and advantages of the present invention will become apparent to those skilled in the art from the following detailed description. It is to be understood, however, that the detailed description and specific examples, while indicating preferred embodiments of the present invention, are given by way of illustration and not limitation. Many changes and modifications within the scope of the present invention may be made without departing from the spirit thereof, and the invention includes all such modifications.

### BRIEF DESCRIPTION OF THE DRAWINGS

FIG. 1 is a flow chart describing a process for preparing a micropattern using a photoresist composition, and

FIG. 2 is a UV spectrum of a polymer produced according to Production Example 3.

### DETAILED DESCRIPTION OF THE INVENTION

Priority Korean Patent application No. 2000-44028, filed Jul. 29, 2000, is incorporated herein in its entirety by reference.

A polymer for a photoresist composition according to the present invention, which is represented by the following formula (I), comprises styrene-type monomers the phenyl groups of which have pendant groups that are easily deprotected by acid, and stilbene monomers:

[chemical structure]

wherein R¹ is a hydrogen atom or a methyl group, R² is a C₁₋₁₂ linear or branched alkyl, haloalkyl or alkoxycarbonyl group, a C₅₋₁₂ cyclic alkyl, cyclic haloalkyl or cyclic alkoxycarbonyl group, a phenyl group or a naphthyl group, R³ is a C₁₋₁₂ linear or branched alkyl or haloalkyl group, a C₅₋₁₂ cyclic alkyl or cyclic haloalkyl group, a phenyl group, or a naphthyl group, R⁴ and R⁵ are independently a hydrogen atom, a C₁₋₆ linear or branched alkyl, or a C₅₋₆ cyclic alkyl group, R′ and R″ are independently a hydrogen atom, a halogen atom, a C₁₋₈ alkyl or alkoxy group, a hydroxy group, a carbonate group or a phenyl group, and m, n, p and q are independently an integer provided that m and q are not zero, at least one of n and p are not zero, 0.4≦m/(m+n+p+q)≦0.9, 0≦n/(m+n+p+q)≦0.5, 0≦p/(m+n+p+q)≦0.5, and 0.01≦q/(m+n+p+q)≦0.3.

The polymer of the formula (I) preferably is produced by anion-polymerizing monomers of the following formula (II) with a stilbene monomer of the following formula (IV), and then at least partially hydrolyzing a repeating unit of the formula (II) which is easily hydrolyzed to make a terpolymer, the repeating unit p of which is zero, or again substituting with an acetal to make a tetrapolymer:

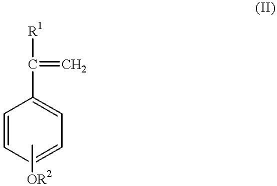

wherein R¹ is a hydrogen atom or a methyl group, and R² is a C₁₋₁₂ linear or branched alkyl, haloalkyl or alkoxycarbonyl group, a C₅₋₁₂ cyclic alkyl, cyclic haloalkyl or cyclic alkoxycarbonyl group, a phenyl group or a naphthyl group.

The molar concentration of the monomers constituting embodiments of the inventive polymer can be controlled by changing the amount of acid which is added as a catalyst, or by changing the amount of the substituted body. Embodiments of the inventive polymer can also be produced through a method comprising the steps of anion-polymerizing monomers of the formula (II) with a stilbene monomer (IV), substituting all repeating unit of the formula (II) with an acetal, and hydrolyzing at least a part of them to make a tetrapolymer.

Concrete examples of the formula (II) include, without limitation, o-, m-, and p-methoxystyrene, ethoxystyrene, propoxystyrene, butoxystyrene, t-butoxystyrene, pentoxystyrene, hexyloxystyrene, cyclohexyloxystyrene, heptoxystyrene, octyloxystyrene, nonyloxystyrene, decyloxystyrene, phenyloxystyrene, naphthyloxystyrene, methoxycarbonyloxystyrene, ethoxycarbonyloxystyrene, propoxycarbonyloxystyrene, butoxycarbonyloxystyrene, isopropoxycarbonyloxystyrene, isobutoxycarbonyloxystyrene, tert-butoxycarbonyloxystyrene, cyclohexyloxycarbonyloxystyrene, etc.

The repeating units substituted with acetal(s) in the above formula (I) can be represented by the following formula (III):

[chemical structure]

wherein R¹ is a hydrogen atom or a methyl group, R³ is a C₁₋₁₂ linear or branched alkyl or haloalkyl group, a C₅₋₁₂ cyclic alkyl or cyclic haloalkyl group, a phenyl group or a naphthyl group, and R⁴ and R⁵ are independently a hydrogen atom, a C₁₋₆ linear or branched alkyl group, or a C₅₋₆ cyclic alkyl group.

Concrete examples of the above monomer (III) include, without limitation, m- or p-1-methoxy-1-methylethoxystyrene, m- or p-1-ethoxyethoxystyrene, m- or p-1-methoxyethoxystyrene, m- or p-1-butoxyethoxystyrene, m- or p-1-isobutoxyethoxystyrene, m- or p-1-(1,1-dimethylethoxy)-1-methylethoxystyrene, m- or p-1-(1,1-dimethylethoxy)ethoxystyrene, m- or p-1-(2-chloroethoxy)ethoxystyrene, m- or p-1-(2-ethylhexyloxy)ethoxystyrene, m or p-1-ethoxy-1-methylethoxystyrene, m- or p-1-n-propoxyethoxystyrene, m- or p-1-methyl-1-n-propoxyethoxystyrene, m- or p-1-ethoxypropoxystyrene, m- or p-1-methoxybutoxystyrene, m- or p-1-methoxycyclohexyloxystyrene, m- or p-1-ethoxycyclohexyloxystyrene, m- or p-1-p-methoxymethyloxystyrene or m-1-p methoxypentyloxystyrene, m-1-p methoxyisobornyloxystyrene, m-1-acetyloxy-1-methylethoxystyrene, m- or p-1-hydroxy-α-methylstyrene, etc.

The stilbene monomer used according to the present invention is of the following formula (IV)

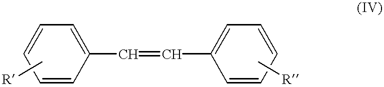

wherein R′ and R″ are independently a hydrogen atom, a halogen atom, a C₁₋₈ alkyl or alkoxy group, a hydroxy group, a carbonate group or a phenyl group. Both cis- and trans-isomers can be used.

Non-limiting examples of the formula (IV) include stilbene, 4-chlorostilbene, 3-bromostilbene, 4-hydroxystilbene, 3-hydroxystilbene, 2-hydroxystilbene, 4-methylstilbene, 3-ethylstilbene, 4-propylstilbene, 4-n-butylstilbene, 2-t-butylstilbene, 3-t-butylstilbene, 4-t-butylstilbene, 3-iso-butylstilbene, 4-n-pentylstilbene, 3-n-hexylstilbene, 4-n-heptylstilbene, 3-n-octylstilbene, 4-methoxystilbene, 4-ethoxystilbene, 3-propoxystilbene, 2-t-butoxystilbene, 3-t-butoxystilbene, 4-t-butoxystilbene, 4-iso-butoxystilbene, 3-n-pentoxystilbene, 4-n-hexoxystilbene, 3-n-heptoxystilbene, 4-n-octoxystilbene, 4-methylcarbonatestilbene, 4-ethylcarbonatestilbene, 4-propylcarbonatestilbene, 2-t-butylcarbonatestilbene, 3-t-butylcarbonatestilbene, 4-t-butylcarbonatestilbene, 4-n-heptylcarbonatestilbene, 4-phenylstilbene, 2-phenylstilbene, and 3-phenylstilbene.

Anion polymerization preferably is performed using an alkyllithium such as n-butyllithium, etc., as an initiator at −70° C., under an N₂ atmosphere in dried THF (tetrahydrofuran). Partial hydrolysis preferably is performed using an acid such as hydrochloric acid, etc. Substitution of the acetal(s) is performed by reacting vinyl ether, etc., under an acid catalyst in a solvent such as THF, etc. The weight average molecular weight of polymer polymerized by these methods preferably is about 5,000 to 30,000, and the molecular weight distribution preferably is about 1.0 to 3.0.

The present invention also provides a composition for photoresist comprising (a) a novel polymer for photoresist according to the present invention, (b) a photo acid generator, and (c) a solvent which can dissolve the components, (a) and (b).

The photo acid generator is one or more compounds selected from the group consisting of the following formulas (V)-(XI). The photoacid generator produces an acid when exposed to light. The preferred content of photo acid generator is about 0.05-15 weight % per polymer 100 weight %.

The formula (V) is as follows:

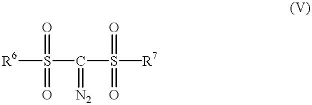

wherein R⁶ and R⁷ are independently a C₁₋₁₀ linear or branched alkyl group, or a C₅₋₁₀ cyclic alkyl group.

Examples of the formula (V) include, without limitation, 1-cyclohexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, etc.

The formula (VI) is as follows:

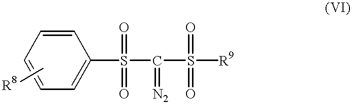

wherein R⁸ is a hydrogen atom, a halogen atom, or a C₁₋₅ linear or branched alkyl, alkoxy, or haloalkyl group, and R⁹ is a C₁₋₁₀ linear or branched alkyl or haloalkyl group, a C₅₋₁₀ cyclic alkyl or haloalkyl group, a phenyl group, a halophenyl group, or a C₇₋₁₀ alkylphenyl or haloalkylphenyl group.

Examples of the formula (VI) include, without limitation, bis(p-toluenesulfonyl)diazomethane, methylsulfonyl-p-toluenesulfonyldiazomethane, bis(p-chlorobenzenesulfonyl)diazomethane, cyclohexylsulfonyl-p-toluenesulfonyldiazomethane, etc.

The formula (VII) is as follows:

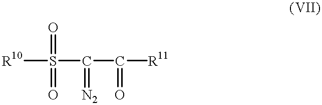

wherein R¹⁰ is a C₁₋₁₀ linear or branched alkyl group, a C₅₋₁₀ cyclic alkyl group, or a group of the formula (VIIA)

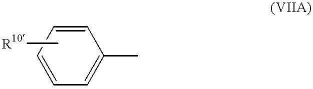

wherein R^{10′} is a hydrogen atom, a halogen atom, a C₁₋₅ linear or branched alkyl group or a trifluoromethyl group, and R¹¹ is a C₁₋₁₀ linear or branched alkyl or haloalkyl group, a phenyl group, a C₇₋₁₀ phenylalkyl or alkylphenyl group (for example a tolyl group), a C₅₋₁₀ cyclic alkyl or haloalkyl group, or a C₁₋₅ linear, or branched alkoxy group.

Non-limiting examples of the formula (VII) include:

1-cyclohexylsulfonyl-1-cyclohexylcarbonyldiazomethane,

1-diazo-1-cyclohexylsulfonyl-3,3-dimethylbutane-2-one,

1-diazo-1-methylsulfonyl-4-phenylbutane-2-one,

1-diazo-1-(1,1-dimethylethylsulfonyl)-3,3-dimethyl-2-butanone,

1-p-toluenesulfonyl-1-cyclohexylcarbonyldiazomethane,

1-diazo-1-(p-toluenesulfonyl)-3,3-dimethylbutane-2-one,

1-diazo-1-benzenesulfonyl-3,3-dimethylbutane-2-one,

1-diazo-1-(p-toluenesulfonyl)-3-methylbutane-2-one, etc.

The formula (VIII) is as follows:

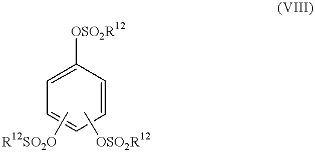

wherein R¹² is represented by the following formula (VIIIA) or (VIIIB):

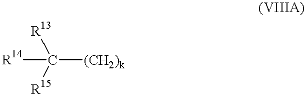

wherein R¹³, R¹⁴ and R¹⁵ are independently a hydrogen atom or a halogen atom, and k is an integer of 0-3; and

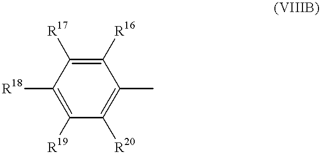

wherein R¹⁶-R²⁰ are independently a hydrogen atom, a halogen atom, a C₁₋₅ linear or branched alkyl or alkoxy group, a trifluoromethyl group, a hydroxy group, a trifluoromethoxy group or a nitro group.

In formula (VIII), the R¹² groups can be the same or different.

Non-limiting examples of the formula (VIII) include:

1,2,3-tris(trifluoromethanesulfonyloxy)benzene,

1,2,3-tris(2,2,2-trifluoroethanesulfonyloxy)benzene,

1,2,3-tris(2-chloroethanesulfonyloxy) benzene,

1,2,3-tris(p-nitrobenzenesulfonyloxy)benzene,

1,2,3-tris(2,3,4,5,6-pentafluorobenzenesulfonyloxy)benzene,

1,2,3-tris(p-fluorobenzenesulfonyloxy) benzene,

1,2,3-tris(methanesulfonyloxy)benzene,

1,2,4-tris(p-trifluoromethoxybenzenesulfonyloxy)benzene,

1,2,4-tris(2,2,2-trifluoroethanesulfonyloxy)benzene,

1,3,5-tris(methanesulfonyloxy)benzene,

1,3,5-tris(trifluoromethanesulfonyloxy) benzene,

1,3,5-tris(2,2,2-trifluoroethanesulfonyloxy)benzene,

1,3,5-tris(p-nitrobenzenesulfonyloxy)benzene,

1,3,5-tris(2,3,4,5,6-pentafluorobenzenesulfonyloxy)benzene,

1,3,5-tris(p-fluorobenzenesulfonyloxy) benzene,

1,3,5-tris(2-chloroethanesulfonyloxy)benzene, etc.

The formula (IX) is as follows:

[chemical structure]

wherein R¹² is represented by the above formula (VIIIA) or (VIIIB), R²¹ is a hydrogen atom, a hydroxy group, or R¹²SO₂O, and R²² is a C₁₋₅ linear or branched alkyl group, or a group represented by the formula (IXA):

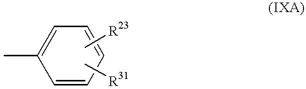

wherein R²³ and R³¹ are independently a hydrogen atom, a C₁₋₅ linear or branched alkyl group or R¹²SO₂O.

Non-limiting examples of the formula (IX) include:

2,3,4-tris(p-fluorobenzenesulfonyloxy)benzophenone,

2,3,4-tris(trifluoromethanesulfonyloxy)benzophenone,

2,3,4-tris(2-chloroethanesulfonyloxy)benzophenone,

2,3,4-tris(p-trifluoromethoxybenzenesulfonyloxy)benzophenone,

2,3,4-tris(p-nitrobenzenesulfonyloxy)benzophenone,

2,3,4-tris(p-fluorobenzenesulfonyloxy)acetophenone,

2,3,4-tris(2,3,4,5,6-pentafluorobenzensulfonyloxy)acetophenone,

2,3,4-tris(2-nitrobenzenesulfonyloxy)acetophenone,

2,3,4-tris(2,5-dichlorobenzenesulfonyloxy)acetophenone,

2,3,4-tris(2,3,4-trichlorobenzenesulfonyloxy)acetophenone,

2,2′,4,4′-tetra(methanesulfonyloxy)benzophenone,

2,2′,4,4′-tetra(2,2,2-trifluoroethanesulfonyloxy)benzophenone,

2,2′,4,4′-tetra(2-chloroethanesulfonyloxy)benzophenone,

2,2′,4,4′-tetra(2,5-dichlorobenzenesulfonyloxy)benzophenone,

2,2′,4,4′-tetra(2,4,6-trimethylbenzenesulfonyloxy)benzophenone,

2,2′,4,4′-tetra(m-trifluoromethylbenzenesulfonyloxy)benzophenone, etc.

The formula (X) is as follows:

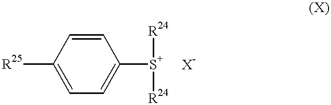

wherein R²⁴ is a C₁₋₆ linear or branched alkyl group, a phenyl group, or a substituted phenylalkyl group, R²⁵ is a hydrogen atom, a halogen atom, a C₁₋₄ linear or branched alkyl group, or a C₅₋₆ cyclic alkyl group, and X is a C₁₋₈ linear or branched alkyl sulfonate or perfluoroalkyl sulfonate, a C₅₋₈ cyclic alkyl sulfonate or perfluoroalkyl sulfonate, naphthyl sulfonate, 10-camphor sulfonate, phenyl sulfonate, tolyl sulfonate, dichlorophenyl sulfonate, trichlorophenyl sulfonate, trifluoromethylphenyl sulfonate, Cl, Br, SbF₆, BF₄, PF₆ or AcF₆.

Non-limiting examples of the formula (X) include triphenylsulfonium trifluoromethanesulfonate, triphenylsulfonium perfluorooctanesulfonate, triphenylsulfonium perfluorobutanesulfonate, diphenyl-p-tolylsulfonium perfluorooctanesulfonate, tris(p-tolyl)sulfonium perfluorooctanesulfonate, tris(p-chlorobenzene)sulfonium trifluoromethanesulfonate, tris(p-tolyl)sulfonium tifluoromethanesulfonate, trimethylsulfonium trifluoromethanesulfonate, dimethylphenylsulfonium trifluoromethanesulfonate, dimethyltolylsulfonium trifluoromethanesulfonate, dimethyltolylsulfonium perfluorooctanesulfonate, triphenylsulfonium p-toluenesulfonate, triphenylsulfonium methanesulfonate, triphenylsulfonium butanesulfonate, triphenylsulfonium n-octanesulfonate, triphenylsulfonium 1-naphthalenesulfonate, triphenylsulfonium 2-naphthalenesulfonate, triphenylsulfonium 10-camphorsulfonate, triphenylsulfonium 2,5-dichlorobenzenesulfonate, diphenyltolylsulfonium 1,3,4-trichlorobenzenesulfonate, dimethyltolylsulfonium p-toluenesulfonate, diphenyltolylsulfonium 2,5-dichlorobenzenesulfonate, triphenylsulfonium tetrafluoroborate, triphenylsulfonium hexafluoroacetate, triphenylsulfonium chloride, etc.

The formula (XI) is as follows:

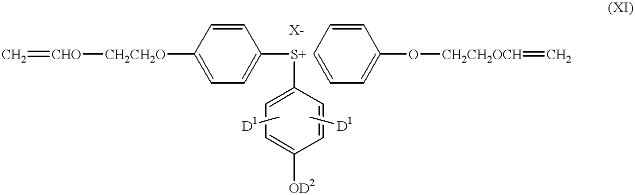

wherein X is a C₁₋₈ linear or branched alkyl sulfonate or perfluoroalkyl sulfonate, a C₅₋₈ cyclic alkyl sulfonate or perfluoroalkyl sulfonate, naphthyl sulfonate, 10-camphor sulfonate, phenyl sulfonate, tolyl sulfonate, dichlorophenyl sulfonate, trichlorophenyl sulfonate, trifluoromethylphenyl sulfonate, F, Cl, Br, SbF₆, BF₄, PF₆ or AcF₆, D¹ is a hydrogen atom or a C₁₋₄ alkyl group, and D² is a C₁₋₁₀ alkyl group or a 2-vinyloxyethyl group.

Non-limiting examples of the formula (XI) include compounds wherein X is methanesulfonate, trifluoromethanesulfonate, p-toluenesulfonate, 10-camphorsulfonate, cyclohexanesulfonate, perfluoro-1-butanesulfonate, perfluorooctanesulfonate, F, Cl, Br, SbF₆, BF₄, PF₆ or AcF₆, D¹ is a hydrogen atom or a methyl group and D²is a methyl group or a vinyloxyethyl group.

The photoresist composition of an embodiment of the present invention can further contain one or more basic materials to improve the pattern property of the composition if necessary. Examples of basic materials include, without limitation, monomers, polymers, phosphine oxide derivatives and hydrazine derivatives having amine group in their structure. The preferred content of each basic material is 10 or less % by weight per 100% by weight of the polymer.

In addition, a surfactant, viscosity agent, adhesive agent, preservation agent, etc., can be included as an additive if needed. Exemplary surfactant materials include, without limitation, ether compounds such as polyoxyethylene lauryl ether, polyoxyethylene stearyl ether, polyoxyethylene oleyl ether, polyoxyethylene nonyl phenyl ether, etc., and chloride compounds such as MEGAFACE R-08 (a trademark, available from Dainippon Ink & Chemicals, Incorp.), Fluorad FC-430 (a trademark, available from Dainippon Ink & Chemicals, Incorp.), MEGAFACE LS-11 (a trademark, available from Dainippon Ink & Chemicals, Incorp.), etc. Amine compounds can be used as a surfactant, viscosity agent, adhesive agent, and preservation agent. The mixing ratio of each additive is preferably about 5 or less % by weight per 100% by weight of the inventive polymer.

As non-limiting examples of a solvent dissolving each component of the inventive photoresist composition, there can be used one or more compounds selected from the group consisting of ethylene glycol monomethyl ether, ethylene glycol monoethyl ether, methyl Cellosolve acetate, ethyl Cellosolve acetate, diethylene glycol monomethyl ether, diethylene glycol monoethyl ether, propylene glycol methyl ether acetate, propylene glycol propyl ether acetate, diethylene glycol dimethyl ether, ethyl lactate, toluene, xylene, methyl ethyl ketone, cyclohexanone, 2-heptanone, 3-heptanone, 4-heptanone, etc. If necessary, an assistant solvent, such as N-methylformamide, N,N-dimethylformamide, N-methylacetamide, N,N-dimethylacetamide, N-methylpyrrolidone, dimethylsulfoxide, alchol, etc., can be used. Preferably, the polymer mixing ratio is about 5-25% by weight per 100% by weight of solvent, and the assistant solvent mixing ratio is about 10 or less % by weight per 100% by weight of solvent.

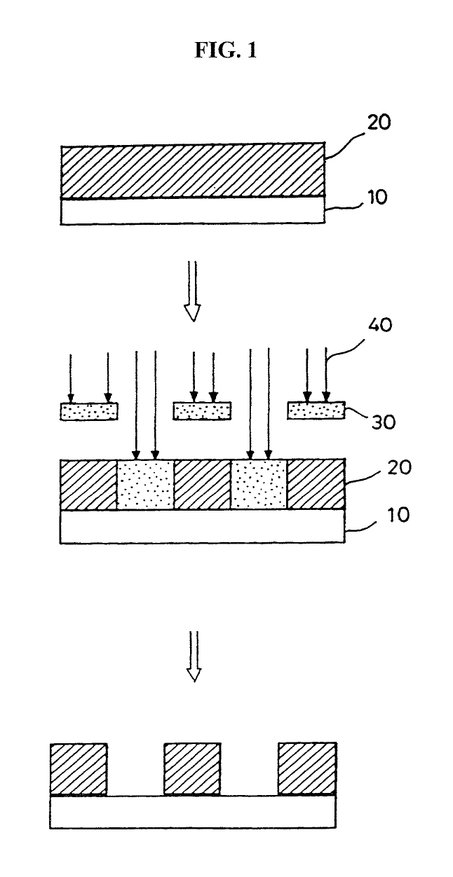

FIG. 1 is a flow chart describing a method of preparing a micropattern using a resist composition. First, a resist composition 20 is coated on substrate 10, such as a silicon wafer, and then dried. The substrate 10 is exposed to a laser 40, preferably a Kr excimer laser having a wavelength of 300 nm or less, through a mask 30, and is developed using an alkali developing solution to form the desired pattern 50.

The present invention can be more clearly understood by reference to the following examples. It should be understood that the following examples are not intended to restrict the scope of the present invention in any manner.

### PRODUCTION EXAMPLE 1

### Production of Poly[p-hydroxystyrene (60 mole %)-co-p-tert-butoxycarbonyloxystyrene (30 mole %)-co-stilbene (10 mole %)]

p-(tert-Butoxycarbonyloxystyrene) (220 g) was dissolved in anhydrous tetrahydrofuran. Trans-stilbene was added thereto and dissolved. Then n-butyllithium (0.5 g) was added and nitrogen gas was supplied to the reactor. An anionic reaction was carried out at −70° C. for 24 hours to obtain a binary polymer. The obtained polymer was again dissolved in hydrofuran, hydrolyzed by adding hydrochloric acid (1.5 g) and washed using distilled water to obtain the above polymer. Yield>95%.

### PRODUCTION EXAMPLE 2

### Production of Poly[p-hydroxystyrene (70 mole %)-co-p-ethoxyethoxystyrene (20 mole %)-co-stilbene (10 mole %)]

p-(tert-Butoxycarbonyloxystyrene) (220 g) was dissolved in anhydrous tetrahydrofuran (500 g). Trans-stilbene was added thereto and dissolved. Then n-butyllithium (0.5 g) was added and nitrogen gas was supplied to the reactor. A reaction was carried out at −70° C. for 24 hours to obtain a binary polymer. The obtained polymer was dissolved in hydrofuran, hydrolyzed by adding hydrochloric acid (20 g) and washed using distilled water to obtain a binary copolymer, poly[p-hydroxystyrene (90 mole %)-co-stilbene (10 mole %)]. After dissolving the obtained polymer (48 g) in tetrahydrofuran (80 g) at room temperature, ethyl vinyl ether (6 g) and p-toluenesulfonic acid (0.1 g) was added and the reaction was carried out for 2 hours. The product polymer was washed using water several times and dried. Yield>95%.

### PRODUCTION EXAMPLE 3

### Production of Poly[p-hydroxystyrene (50 mole %)-co-p-tert-butoxycarbonyloxystyrene (30 mole %)-co-stilbene (10 mole %)-co-p-ethoxyethoxystyrene (10 mole %)]

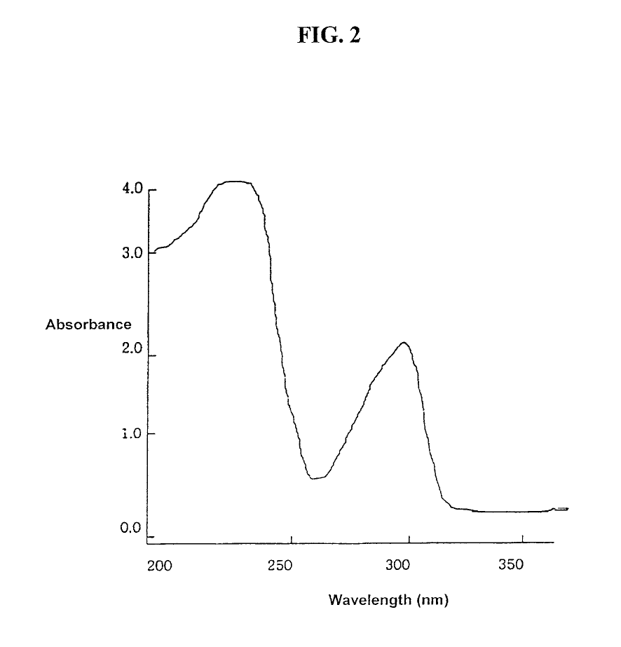

The polymer (120 g) obtained in Production Example 1 was dissolved in tetrahydrofuran (400 g). Ethyl vinyl ether (10 g) and p-toluenesulfonic acid (0.03 g) as an acid catalyst were added thereto. Then a reaction was carried out at room temperature for 10 hours. The reaction solution was poured into water and the polymer of weight average molecular weight 2000 and molecular distribution 1.6 was obtained. Yield>95%. FIG. 2 is a UV spectrum of the obtained polymer. The polymer has good light transmittance at 248 nm.

### EXAMPLE 1

Poly[p-hydroxystyrene (50 mole %)-co-p-tert-butoxycarbonyloxystyrene (30 mole %)-co-stilbene (10 mole %)-co-p-ethoxyethoxystyrene (10 mole %)] (weight average molecular weight 22,000, molecular weight distribution 1.6) obtained in Production Example 3 (100 g), triphenylsulfonium p-toluenesulfonate (0.8 g), 1,2,3-tris(trifluoromethanesulfonyloxy)benzene (0.2 g) and 1-diazo-1-(p-toluenesulfonyl)-3-methylbutane-2-one (0.8 g) were dissolved in propylene glycol methyl ether acetate to obtain a photoresist composition.

The photoresist composition was spin-coated on a silicon wafer, and preheated at 90° C. for 90 sec to form a 0.8 micron thick resist film. Then the resist film was exposed to a KrF excimer laser (248 nm) through a mask having a desired pattern using a KrF excimer laser stepper, and heated again at 110° C. for 90 sec. Then the substrate was puddle-developed in tetramethylammonium hydroxide aqueous solution for 1 minute, rinsed using ultra pure water, and spin-dried. A positive pattern of 0.2 micron line and space was developed with good pattern shape. Further, the field, which was not exposed to light, did not deteriorate, and after development, deterioration of the exposed field was not observed.

For evaluation of etch resistance, a 0.8 micron thick resist film was tested using a reactive ion etching machine of the parallel flat board type under the following conditions: 200 W, 100 scm and 0.02 torr. The resist film was etched at the rate of 0.45 micron/min.

### EXAMPLE 2

The same method of Example 1 was followed except that poly[p-hydroxystyrene (55 mole %)-co-p-cyclohexaneoxystyrene (15 mole %)-co-p-(1-benzyloxy-1-methylethoxy)styrene (20 mole %)-co-trans-stilbene (10 mole %)] (weight average molecular weight 20,000, molecular weight distribution 1.7) (100 g) was used as a binder resin. The etching property was evaluated using the same method as Example 1. A positive pattern of 0.17 micron line and space was developed with good pattern shape. Further, the field, which was not exposed to light, did not deteriorate, and after development, deterioration of the exposed field was not observed. In the test for evaluation of etch resistance, 0.48 micron/min was obtained.

### EXAMPLE 3

Poly[p-hydroxystyrene (65 mole %)-co-p-ethoxystyrene (20 mole %)-co-trans-stilbene (15 mole %)] (weight average molecular weight 18,000, molecular weight distribution 1.7) (100 g), bis(p-toluenesulfonyl)diazomethane (0.5 g), and dimethyltolylsulfonium perfluorooctanesulfonate (1 g) were dissolved in a mixed solution (720 g) of ethyl Cellosolve acetate and methyl ethyl ketone to obtain a photoresist composition.

The etching property of the composition was evaluated using the same method of Example 1. A positive pattern of 0.18 micron line and space was developed with good pattern shape. Further, the field, which was not exposed to light, did not deteriorate, and after development, deterioration of the exposed part was not observed. In the test for evaluation of etch resistance, 0.46 micron/min was obtained.

### EXAMPLE 4

The same method of Example 1 was followed, except that poly[p-hydroxystyrene (72 mole %)-co-p-1-ethoxyethoxystyrene (20 mole %)-co-trans-stilbene (8 mole %)] (weight average molecular weight 25,000, molecular weight distribution 1.5) (100 g) was used as a binder resin.

The etching property of the composition was evaluated using the same method of Example 1. A positive pattern of 0.22 micron line and space was developed with good pattern shape. Further the field, which was not exposed to light, did not deteriorate, and after development, deterioration of the exposed part was not observed. In the test for valuation of etch resistance, 0.43 micron/min was obtained.

### EXAMPLE 5

Poly[p-hydroxystyrene (65 mole %)-co-p-methoxystyrene (10 mole %)-co-p-ethoxyethoxystyrene (15 mole %)-co-trans-stilbene (10 mole %)] (weight average molecular weight 21,000, molecular weight distribution 1.8) (100 g) and the same kind and the same amount of photoacid generators used in Example 1 were dissolved in a mixed solvent (750 g) of propylene glycol propyl ether acetate and xylene to obtain a photoresist composition.

The etch property was evaluated using the same method of Example 1. A positive pattern of 0.24 micron line and space was developed with good pattern shape. Further, the field, which was not exposed to light, did not deteriorate, and after development, deterioration of the exposed part was not observed. In the test for evaluation of etch resistance, 0.41 micron/min was obtained.

### COMPARATIVE EXAMPLE 1

Poly[p-hydroxystyrene (60 mole %)-co-p-tert-butoxycarbonyloxystyrene (30 mole %)-co-p-ethoxyethoxystyrene (10 mole %)], excluding trans-stilbene monomer from the binder resin used in Example 1 (100 g), triphenylsulfonium p-toluenesulfonate (0.8 g), 1,2,3-tris(trifluoromethanesulfonyloxy)benzene (0.2 g) and 1-diazo-1-(p-toluenesulfonyl)-3-methylbutane-2-one (0.8 g) were dissolved in propylene glycol methyl ether acetate to obtain a photoresist composition. The etching property was evaluated using the same method of Example 1. The best value of line and space was 0.24 micron. In the test for evaluation of etch resistance, a value of 0.52 micron/min, which is worse than Example 1, was obtained.

### COMPARATIVE EXAMPLE 2

The same method as Example 2 was followed, except that poly[p-hydroxystyrene (65 mole %)-co-p-cyclohexaneoxystyrene (15 mole %)-co-p-(1-benzyloxy-1-methylethoxy)styrene (20 mole %)], excluding stilbene monomer from the binder resin used in Example 2, was used. The best value of line and space was 0.28 micron. In the test for evaluation of etch resistance, a value of 0.54 micron/min, which is worse than Example 2, was obtained.

### COMPARATIVE EXAMPLE 3

The same method of Example 3 was followed, except that poly[p-hydroxystyrene (80 mole %)-co-p-ethoxystyrene (20 mole %)], excluding stilbene monomer from the binder resin used in Example 3, was used. The best value of line and space was 0.28 micron. In the test for evaluation of etch resistance, a value of 0.55 micron/min, which is worse than Example 3, was obtained.

What is claimed is:

1. A polymer for a photoresist composition, the polymer being represented by the formula (I): [chemical structure]
wherein R¹ is a hydrogen atom or a methyl group, R² is a C₁₋₁₂ linear or branched alkyl, haloalkyl or alkoxycarbonyl group, a C₅₋₁₂ cyclic alkyl, cyclic haloalkyl or cyclic alkoxycarbonyl group, a phenyl group or a naphthyl group, R³ is a C₁₋₁₂ linear or branched alkyl or haloalkyl group, a C₅₋₁₂ cyclic alkyl or cyclic haloalkyl group, a phenyl group, or a naphthyl group, R⁴ and R⁵ are independently a hydrogen atom, a C₁₋₆ linear or branched alkyl, or a C₅₋₆ cyclic alkyl group, R′ and R″ are independently a hydrogen atom, a halogen atom, a C₁₋₈ alkyl or alkoxy group, a hydroxy group, a carbonate group or a phenyl group, and m, n, p and q are independently an integer provided that m and q are not zero, at least one of n and p are not zero, 0.4≦m/(m+n+p+q)≦0.9, 0≦n/(m+n+p+q)≦0.5, 0≦p/(m+n+p+q)≦0.5, and 0.01≦q/(m+n+p+q)≦0.3.

2. A photoresist composition comprising
(a) a polymer according to claim 1,
(b) a photo acid generator, and
(c) a solvent which dissolves the components, (a) and (b).

3. A photoresist composition according to claim 2 wherein the photoacid generator is selected from the group consisting of compounds of formulas (V) to (XI): 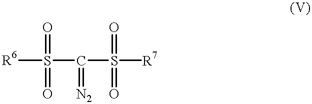
wherein R⁶ and R⁷ are independently a C₁₋₁₀ linear or branched alkyl group, or a C₅₋₁₀ cyclic alkyl group; 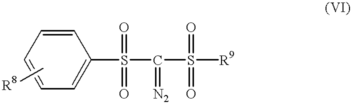
wherein R⁸ is a hydrogen atom, a halogen atom, or a C₁₋₅ linear or branched alkyl, alkoxy, or haloalkyl group, and R⁹ is a C₁₋₁₀ linear or branched alkyl or haloalkyl group, a C₅₋₁₀ cyclic alkyl or haloalkyl group, a phenyl group, a halophenyl group, or a C₇₋₁₀ alkylphenyl or haloalkylphenyl group; 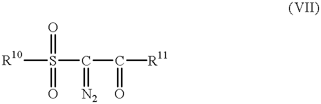
wherein R¹⁰ is a C₁₋₁₀ linear or branched alkyl group, a C₅₋₁₀ cyclic alkyl group, or a group of the formula (VIIA) 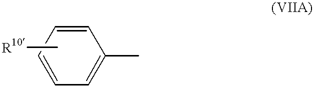
wherein R^{10′} is a hydrogen atom, a halogen atom, a C₁₋₅ linear or branched alkyl group or a trifluoromethyl group, and R¹¹ is a C₁₋₁₀ linear or branched alkyl or haloalkyl group, a phenyl group, a C₇₋₁₀ phenylalkyl or alkylphenyl group, a C₅₋₁₀ cyclic alkyl or haloalkyl group, or a C₁₋₅ linear or branched alkoxy group; 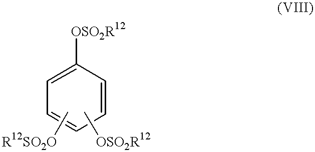
wherein each R¹² is independently represented by the following formula (VIIIA) or (VIIIB): 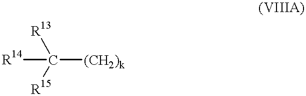
wherein R¹³, R¹⁴ and R¹⁵ are independently a hydrogen atom or a halogen atom, and k is an integer of 0-3; and 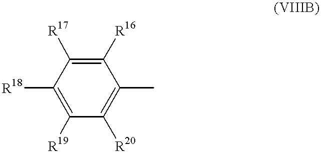
wherein R¹⁶-R²⁰ are independently a hydrogen atom, a halogen atom, a C₁₋₅ linear or branched alkyl or alkoxy group, a trifluoromethyl group, a hydroxy group, a trifluoromethoxy group or a nitro group; [chemical structure]
wherein R¹² is represented by the above formula (VIIIA) or (VIIIB), R²¹ is a hydrogen atom, a hydroxy group, or R¹²SO₂O, and R²² is a C₁₋₅ linear or branched alkyl group, or a group represented by the formula (IXA): 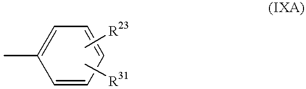
wherein R²³ and R³¹ are independently a hydrogen atom, a C₁₋₅ linear or branched alkyl or R¹²SO₂O; 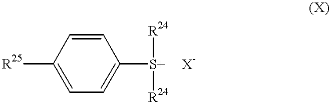
wherein R²⁴ is a C₁₋₆ linear or branched alkyl group, a phenyl group, or a substituted phenylalkyl group, R²⁵ is a hydrogen atom, a halogen atom, a C₁₋₄ linear or branched alkyl group, or a C₅₋₆ cyclic alkyl group, and X is a C₁₋₈ linear or branched alkyl sulfonate or perfluoroalkyl sulfonate, a C₅₋₈ cyclic alkyl sulfonate or perfluoroalkyl sulfonate, naphthyl sulfonate, 10-camphor sulfonate, phenyl sulfonate, tolyl sulfonate, dichlorophenyl sulfonate, trichlorophenyl sulfonate, trifluoromethylphenyl sulfonate, Cl, Br, SbF₆, BF₄, PF₆ or AcF₆; 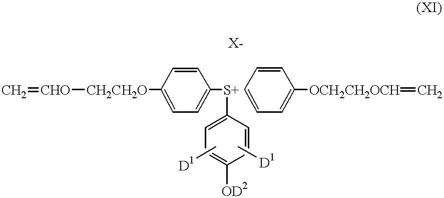
wherein X is a C₁₋₈ linear or branched alkyl sulfonate or perfluoroalkyl sulfonate, a C₅₋₈ cyclic alkyl sulfonate or perfluoroalkyl sulfonate, naphthyl sulfonate, 10-camphor sulfonate, phenyl sulfonate, tolyl sulfonate, dichlorophenyl sulfonate, trichlorophenyl sulfonate, trifluoromethylphenyl sulfonate, F, Cl, Br, SbF₆, BF₄, PF₆ or AcF₆, D¹ is a hydrogen atom or a C₁₋₄ alkyl group, and D² is a C₁₋₁₀ alkyl group or a 2-vinyloxyethyl group; and mixtures thereof.

4. A photoresist composition according to claim 2 wherein the solvent is selected from the group consisting of ethylene glycol monomethyl ether, ethylene glycol monoethyl ether, methyl Cellosolve acetate, ethyl Cellosolve acetate, diethylene glycol monomethyl ether, diethylene glycol monoethyl ether, propylene glycol methyl ether acetate, prolylene glycol propyl ether acetate, diethylene glycol dimethyl ether, ethyl lactate, toluene, xylene, methyl ethyl ketone, cyclohexanone, 2-heptanone, 3-heptanone, 4-heptanone, and mixtures thereof.

5. A photoresist composition according to claim 4, wherein the solvent further contains at least one compound selected from the group consisting of N-methylformamide, N,N-dimethylformamide, N-methylacetamide, N,N-dimethylacetamide, N-methylpyrrolidone, dimethylsulfoxide, alcohols, and mixtures thereof.

6. A method for producing a polymer of claim 1, the method comprising the steps of
(i) anion-polymerizing at least one monomer of the following formula (II) 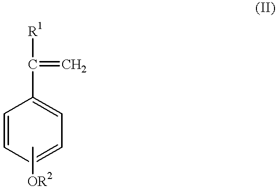
wherein R¹ is a hydrogen atom or a methyl group, and R² is a C₁₋₁₂ linear or branched alkyl, haloalkyl or alkoxycarbonyl group, a C₅₋₁₂ cyclic alkyl, cyclic haloalkyl or cyclic alkoxycarbonyl group, a phenyl group or a naphthyl group, with a stilbene monomer of the following formula (IV) 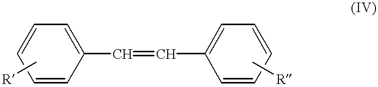
wherein R′ and R″ are independently a hydrogen atom, a halogen atom, a C₁₋₈ alkyl or alkoxy group, a hydroxy group, a carbonate group or a phenyl group, and
(ii) hydrolyzing or substituting with an acetal at least a portion of the polymerized monomer of the formula (II).

7. The method according to claim 6, wherein at least a portion of the polymerized monomer of the formula (II) is substituted with an acetal to afford repeating units having a structure of the formula (III) 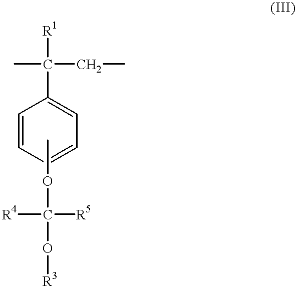
wherein R¹ is a hydrogen atom or a methyl group, R³ is a C₁₋₁₂ linear or branched alkyl or haloalkyl group, a C₅₋₁₂ cyclic alkyl or cyclic haloalkyl group, a phenyl group or a naphthyl group, and R⁴ and R⁵ are independently a hydrogen atom, a C₁₋₆ linear or branched alkyl group, or a C₅₋₆ cyclic alkyl group.

8. A method for producing a polymer of claim 1, the method comprising the steps of:
(i) anion-polymerizing at least one monomer of the following formula (II) 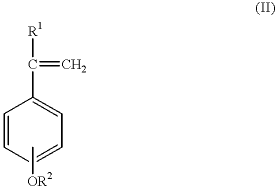
wherein R¹ is a hydrogen atom or a methyl group, and R² is a C₁₋₁₂ linear or branched alkyl, haloalkyl or alkoxycarbonyl group, a C₅₋₁₂ cyclic alkyl, cyclic haloalkyl or cyclic alkoxycarbonyl group, a phenyl group or a naphthyl group,
with a stilbene monomer of the following formula (IV) 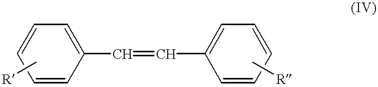
wherein R′ and R″ are independently a hydrogen atom, a halogen atom, a C₁₋₈ alkyl or alkoxy group, a hydroxy group, a carbonate group or a phenyl group,
(ii) substituting the polymerized monomer of the formula (II) with an acetal, and
(ii) hydrolyzing at least a portion of the acetals.
